(19) United States
(12) Patent Application Publication
(10) Pub. No.: US 2007/0126457 A1
(43) Pub. Date: Jun. 7, 2007

(54) Wafer holder, and heating unit and wafer prober provided with the wafer holder

(75) Inventors: Masuhiro Natsuhara, Itami-shi (JP); Tomoyuki Awazu, Itami-shi (JP); Hirohiko Nakata, Itami-shi (JP); Katsuhiro Itakura, Itami-shi (JP)

Correspondence Address: GLOBAL IP COUNSELORS, LLP, 1233 20TH STREET, NW, SUITE 700, WASHINGTON, DC, 20036-2680, US

(73) Assignee: Sumitomo Electric Industries, Ltd., Osaka-shi (JP)

(21) Appl. No.: 11/603,233

(22) Filed: Nov. 22, 2006

(30) Foreign Application Priority Data
Nov. 24, 2005 (JP) 2005-338255

(51) Int. Cl. G01R 31/26

(52) U.S. Cl. 324/765

(57) ABSTRACT

A wafer holder is provided with a mounting stage having a mounting surface for mounting a wafer, and a holding member for holding the mounting stage, wherein relationships are established such that K1>K2 and Y1<Y2, where K1 is the thermal conductivity of the mounting stage, Y1 is the Young's modulus of the mounting stage, K2 is the thermal conductivity of the holding member, and Y2 is the Young's modulus of the holding member. The wafer holder preferably comprises a supporting member on the lower part of the holding member, wherein a relationship is establish such that K2>K3, where K3 is the thermal conductivity of the holding member.

### TECHNICAL FIELD OF THE INVENTION

The present invention relates to a wafer holder having exceptional heating uniformity and rigidity. In particular the present invention relates to a wafer holder and a heater unit used in a wafer prober for mounting a semiconductor wafer on a wafer-mounting surface and pressing a probe card against the wafer to inspect the electrical characteristics of the wafer, and to a wafer prober on which the wafer holder and the heater are mounted.

### BACKGROUND OF THE INVENTION

In the prior art, a heating procedure is performed in a semiconductor inspection step on a semiconductor substrate (wafer) to be treated. Specifically, the wafer is heated to a temperature higher than the normal operating temperature, potentially defective semiconductor chips are made to fail at an accelerated rate and are removed, and a burn-in is performed to prevent the occurrence of defects after shipping. In the burn-in step, after the semiconductor circuits are formed on the semiconductor wafer and before the wafer is diced into individual chips, the electrical characteristics of each chip are measured while the wafer is heated, and defective chips are removed. A strong demand has existed for the processing time to be reduced in the burn-in step in order to improve throughput.

In such a burn-in step, the semiconductor substrate is supported and heated using a heater. Since the entire reverse surface of the wafer must be in contact with a ground electrode, conventional heaters have been made of metal. A wafer on which circuits are formed is mounted on a metal flat-plate heater, and the electrical characteristics of the chips are measured. A measuring instrument called a probe card, which is provided with numerous electrically conductive electrode pins, is pressed onto the wafer with a force of tens to hundreds of kilograms-force (kgf) when the measurements are made. Therefore, if the heater is thin, the heater may be deformed, causing contact failure to occur between the wafer and the probe pin. Therefore, the use of thick metal plates having a thickness of 15 mm or greater has been necessary in order to preserve the rigidity of the heater, and long periods are required for raising and lowering the temperature of the heater, which has become a large obstacle to improving throughput.

Additionally, in the burn-in step, electricity is applied to the chips, and the electrical characteristics are measured. However, with the increasing power output of chips in recent years, the chips generate large amounts of heat when the electrical characteristics are measured, and are sometimes damaged by the heat they generate. Rapid cooling after measurement has therefore been needed. Additionally, heating needs to be as uniform as possible during measurement. Copper (Cu), which has a high thermal conductivity of 403 W/mK, has therefore been used as the metal material.

Accordingly, in Japanese Laid-Open Patent Application Publication No. 2001-033484, a wafer prober is proposed wherein a thin metal layer and not a thick metal plate is formed on the surface of a thin but highly rigid ceramic substrate, resulting in minimized deformation and a low heat capacity. Since this wafer prober has high rigidity, contact failures do not occur. Since this wafer prober has low heat capacity, the temperature can be raised and lowered in a short time. Also disclosed is the use of an aluminum alloy, stainless steel or the like for the support member used to position the wafer prober.

However, if, as disclosed in the aforesaid reference, the wafer prober is only supported at the outermost periphery, the wafer prober may bend due to the pressure of the probe card. Therefore, measures such as providing a large number of support pillars or the like have been necessary.

Furthermore, with the scale of the semiconductor process decreasing over the past several years, a demand has arisen for increased load per unit area during probing and for precise alignment between the probe card and prober. The prober usually repeatedly performs an operation in which the wafer is heated to a predetermined temperature, and moved to a predetermined position during probing, whereupon a probe card is pressed on the wafer. In this case, high precision is also required in the drive system in order to move the prober to the predetermined position.

However, when the wafer is heated to a prescribed temperature; i.e., to about 100° C. to about 200° C., the heat is conveyed to the drive system, and problems have arisen in regard to a loss of precision due to thermal expansion of the metal components in the drive system. Furthermore, due to the increased load during probing, the wafer-holding prober itself must be rigid. Specifically, problems have been presented in that, if the prober itself deforms under load during probing, the pins of the probe card will not be able to make uniform contact with the wafer, thereby rendering inspection impossible, or, in the worst case, damaging the wafer. For this reason, probers are made larger in order to inhibit deformation, and problems have arisen in that the weight of the prober increases and the increased weight affects the precision of the drive system. A problem also arises in that as the size of the prober increases, much more time is required to increase or reduce the temperature of the prober, and throughput decreases.

A cooling mechanism is often provided in order to improve throughput and in order to improve the rate at which the temperature of the prober is raised or lowered. However, in the prior art, the cooling mechanism is air cooling, e.g., as in Japanese Published Laid-Open Patent Application Publication No. 2001-033484, or a cooling plate is provided directly below a heater made from metal. In the case of the former, a problem arises in that the prober is air-cooled, which results in a slow cooling rate. In the case of the latter, a problem arises in that pressure is applied directly to the cooling board during probing by the probe card, and deformation therefore readily occurs.

When semiconductors are manufactured, a heater unit used to heat a semiconductor substrate or other object is used in order to heat-dry a resist liquid that is coated on the substrate in, e.g., a lithography step. In such semiconductor production, the cost of the product is reduced by mass production, which is achieved via continual operation. For this reason, a desire exists for the cycle time of the manufacturing device to be reduced. Achieving a high throughput in a single device requires time to process the target material while the temperature is kept constant, as shall be apparent, as well as a reduction in the time needed to change the temperature of the heater that occurs when the processing conditions (heating time or cooling time) change. For this reason, a technique such as has been disclosed in Japanese Published Unexamined Patent Application No. 2004-014655 is proposed, wherein a cooling block having the desired heat capacity is made to contact to a heated heater substrate, whereby the temperatures of the heater substrate and the target object mounted on the heater substrate can be reduced in a short period of time, resulting in a reduction in the amount of time required for the thermal processing step. However, in this invention, an interface is present between the cooling block and the heater. Therefore, a problem arises in that contact resistance is generated, and the cooling rate cannot be increased past a certain level.

### SUMMARY OF THE INVENTION

The present invention was devised in order to resolve the foregoing problems. Specifically, it is an object of the present invention to provide a wafer holder having high rigidity, as well as a heightened heat-insulating effect that allows positional accuracy and heating uniformity to be improved, chips to be rapidly heated and cooled, and manufacturing costs to be reduced; and a wafer prober device on which the wafer holder is mounted.

The wafer holder of the present invention is a wafer holder comprising a mounting stage having a mounting surface configured and arranged to mount a wafer, and a holding member configured and arranged to hold the mounting stage, wherein relationships are established such that K1>K2 and Y1<Y2, where K1 is the thermal conductivity of the mounting stage, Y1 is the Young's modulus of the mounting stage, K2 is the thermal conductivity of the holding member, and Y2 is the Young's modulus of the holding member. The wafer holder preferably comprises a supporting member on the lower part of the holding member, wherein a relationship is establish such that K2>K3, where K3 is the thermal conductivity of the holding member.

The wafer holder preferably has a cooling module on the lower surface of the holding member, and preferably also has a heat generator on the lower surface of the holding member. Further, the wafer holder preferably has a cooling module and has a heat generator below the cooling module.

The supporting member preferably has a plurality of columnar members configured and arranged to support the holding member.

A suction hole and groove for suctioning an object to be mounted are preferably formed on the mounting stage, and a suction hole and groove for suctioning the holding member are preferably formed on the mounting stage.

A heater unit comprising such a wafer holder, and a wafer prober comprising the heater unit have high rigidity and enhance the thermal-insulating effect, whereby positional accuracy is improved, heating uniformity is improved, and chips can be rapidly heated or cooled.

### BRIEF DESCRIPTION OF THE DRAWINGS

FIG. 1 shows an example of a cross-sectional structure of the wafer holder of the present invention;

FIG. 2 shows an example of the wafer-mounting surface of the wafer holder of the present invention;

FIG. 3 shows an example of another cross-sectional structure of the wafer holder of the present invention;

FIG. 4 shows an example of a cross-sectional structure of the heater of the present invention;

FIG. 5 shows an example of a plan view of the supporting member of the present invention;

FIG. 6 shows an example of a plan view of the cooling module of the present invention;

FIG. 7 shows an example of another plan view of the supporting member of the present invention;

FIG. 8 shows an example of yet another plan view of the supporting member of the present invention; and

FIG. 9 shows another example of a cross-sectional structure of the wafer holder of the present invention.

### DETAILED DESCRIPTION OF THE INVENTION

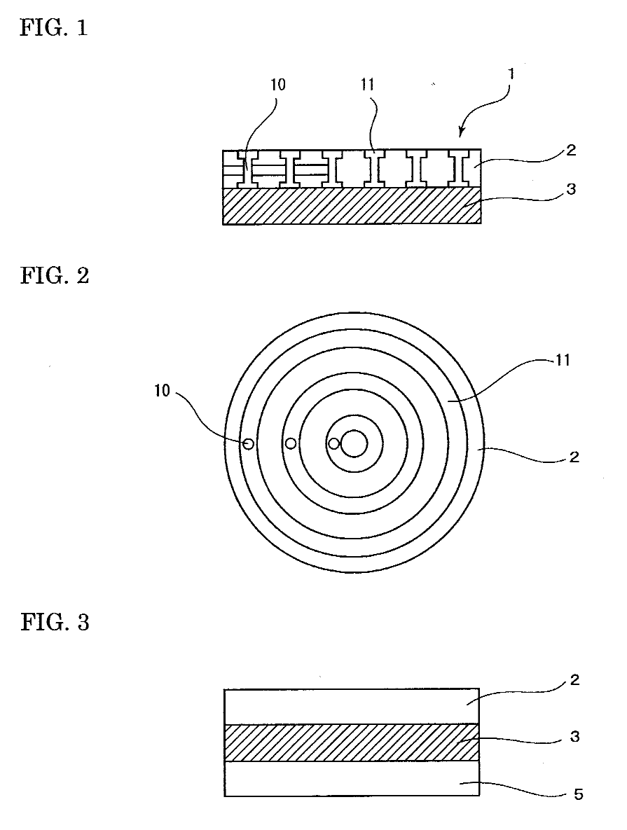

An embodiment of the present invention shall be described with reference to FIG. 1. FIG. 1 is an example of an embodiment of the present invention. The wafer holder 1 of the present invention comprises a mounting stage 2 for mounting a wafer, and a holding member 3 for holding the mounting stage. Relationships are established such that K1>K2 and Y1<Y2, where K1 is the thermal conductivity of the mounting stage at normal temperature, Y1 is the Young's modulus of the mounting stage, K2 is the thermal conductivity of the holding member at normal temperature, and Y2 is the Young's modulus of the holding member.

The heating uniformity of the wafer-mounting surface of the mounting stage can be improved by making the thermal conductivity of the mounting stage greater than the thermal conductivity of the holding member. For example, when a heat generator for heating the wafer is provided to the lower part of the holding member, heat generated by the heat generator is transmitted through the holding member and mounting stage, and the wafer is heated. Heat that is transmitted to the front surface (on the mounting stage side) of the holding member can be diffused through the entire body of the mounting surface and heating uniformity can be improved over that of the front surface of the holding member by increasing the thermal conductivity of the mounting stage. In other words, heating uniformity can be improved even when the thermal conductivity of the holding member is low by virtue of the high thermal conductivity of the mounting stage. Specifically, the temperature can be made uniform by the high thermal conductivity of the mounting stage even if the surface of the holding member that contacts with the mounting stage has poor heating uniformity.

The thermal conductivity of the mounting stage must be high in order to improve heating uniformity. However, when the wafer holder of the present invention is used as an inspection device such as a wafer prober, the entire body of the wafer holder must also be rigid. For this reason, in the present invention, a holding member having a higher Young's modulus than the mounting stage is provided to the opposite side of the wafer-mounting surface of the mounting stage. A wafer holder whose wafer-mounting surface has exceptional heating uniformity and rigidity can be obtained by employing such a configuration.

There are no particular limitations regarding the material of the mounting stage. However, a material having high thermal conductivity, particularly 100 W/mK or greater is preferred in order to improve the heating uniformity of the wafer-mounting surface. Materials that satisfy this condition include metals such as copper, aluminum, tungsten, and molybdenum. Examples of ceramic materials that can be used include aluminum nitride (AlN), silicon carbide (SiC), and silicon nitride (Si₃N₄). Examples of metal and ceramic complexes that can be used include aluminum or silicon and silicon carbide, and complexes of aluminum nitride and the like (Al—SiC, Al—AiN, Si—SiC, and Si—AiN).

There are no particular limitations regarding the material used for the holding member. However, materials having a high Young's modulus are preferably used in order to enhance the rigidity of the holding member. Specific examples of materials that can be used include metals such as tungsten or molybdenum; ceramic materials such as silicon carbide, alumina, aluminum nitride, silicon nitride; and complexes such as aluminum or silicon and silicon carbide or aluminum nitride. Rigidity is an extremely important characteristic in the holding member, but the thermal conductivity thereof is also preferably high. This will enable the holding member to quickly transmit heat or cool air from a heater, cooling module, or other temperature-control mechanism that can be provided to the lower part of the holding member, and will yield a highly responsive holding member. Based on such considerations, materials mentioned above that can be used in particular are the metals tungsten and molybdenum; silicon carbide, aluminum nitride, silicon nitride, and other ceramic materials; and complexes composed of aluminum or silicon and silicon carbide or aluminum nitride. The Young's modulus of the holding member is more preferably 200 GPa or greater. The use of a material having a Young's modulus of 200 GPa or greater is particularly preferable in that deformation of the holding member will dramatically decrease, and the holding member can therefore be made thinner and lighter.

Among combinations such as those described above, relationships are established such that K1>K2 and Y1<Y2 where K1 is the thermal conductivity of the mounting stage at normal temperature, Y1 is the Young's modulus of the mounting stage, K2 is the thermal conductivity of the holding member, and Y2 is the Young's modulus of the holding member. Accordingly, the mounting stage acts to improve the heating uniformity of the wafer-mounting surface and the holding member acts to maintain rigidity. A low-cost wafer holder can thus be formed.

A wafer must be suctioned and fixed to the mounting stage. Therefore, a hole 10 or groove 11 for vacuum suctioning must be formed. When the hole or groove is formed, a mechanical process is generally performed. A material that is conducive to mechanical processing is therefore preferred. For this reason, a material having higher thermal conductivity and a lower Young's modulus than the holding member is preferred.

Accordingly, as a best mode, copper or a copper alloy can be used for the mounting stage as a material having high thermal conductivity; and tungsten, SiC, or an Si and SiC complex (Si—SiC), which have high rigidity, can be used for the holding member. In addition, aluminum or an alloy thereof can be used for the mounting stage and SiC or Si—SiC can be used for the holding member in order to make the wafer holder lighter.

If copper or aluminum is used for the mounting stage, holes are formed therein or another mechanical process for use in vacuum suctioning is performed thereon in order to hold a wafer. The cost is therefore lower than when the process is performed on, e.g., tungsten, Si—SiC, or another material having high rigidity (Young's modulus).

A groove or hole for vacuum suctioning can also be mechanically processed into the surface of the mounting stage on the side opposite the wafer-mounting surface, as shown in FIG. 1. Accordingly, vacuum-suctioning can be performed between the mounting stage and holding member when the wafer is mounted and vacuum-suctioned. Therefore, adhesion between the holding member and mounting stage is improved and heat or cool air can be made to move smoothly from the heat generator or cooling modulus. The mounting stage and holding member can also be screwed or otherwise mechanically fixed together. Combining such techniques will allow the adhesion between the mounting stage and holding member to be maintained and will improve the rate at which heat is transmitted.

A conducting layer can be formed on the wafer-mounting surface of the mounting stage. The layer is formed in order to protect the mounting stage from corrosive gasses, acids, alkali chemicals, organic solvents, water, and other substances commonly used in semiconductor manufacturing processes; and/or to prevent electromagnetic noise originating below the mounting stage from entering the space below the wafer mounted on the mounting stage. The conductor layer therefore acts as a grounder.

There are no particular limitations regarding the method used to form the conducting layer. Examples of methods include applying a conductive paste by screen printing and then firing the resulting material, as well as vapor deposition, sputtering, spraying, plating, or another method. Among these methods, spraying and plating are particularly favorable. No heat treatment is performed when the conducting layer is formed with these methods. Therefore, the mounting stage will not warp due to a heat treatment, and the cost is relatively low, resulting in an inexpensive conducting layer having exceptional characteristics. Plated films in particular are denser and have higher electrical conductivity than sprayed films, and are therefore especially preferable. Nickel and gold are examples of materials that are used in plating and spraying. These materials have relatively high electrical conductivity and exceptional resistance to oxidation, and are therefore preferable.

The surface roughness Ra of the conducting layer is preferably 0.5 μm or less. If the surface roughness exceeds 0.5 μm, then when an element having a high heating value is measured, the heat generated by the element itself during probing will be impossible to disperse from the conducting layer or mounting stage, the temperature of the element will increase, and thermal fracturing may occur. A surface roughness Ra of 0.02 μm or less allows for the efficient dispersal of heat, and is therefore preferable.

A plating film composed of, e.g., copper, gold, or silver, which have high electrical conductivity, can also be formed on the mounting surface. A plating film that is, e.g., 100 μm thick or greater will allow the temperature distribution on the mounting surface to be made relatively uniform, and is therefore preferable. In such instances, the above-described copper, gold, or silver plating layer can be formed after, e.g., a nickel plating has been formed in order to preserve the adhesion between the holding member and the plating film formed on the holding member. Gold plating can also be applied after, e.g., a highly electrically conductive copper plating film has been formed in order to impart anti-oxidation characteristics and chemical resistance.

The plating film preferably has a thickness of 100 μm or more in order to improve heating uniformity. If the plating thickness is less than 100 μm, the effect of making the temperature of the wafer-mounting surface more uniform will deteriorate. There is no particular upper limit to the thickness of the plating film. Once the plating film has thus been formed, a groove or holes for suctioning the wafer can be formed, and a wafer-mounting surface can be formed by grinding the mounting surface. In such a process, relative to when a rigid holding member is processed, the depth of the grooves on the holding member can be reduced by an amount corresponding to the thickness of the plating in order to process the mounting surface, and, in particular, in order to process the wafer-mounting surface. Therefore, the surface can be processed less expensively than when the holding member itself is processed. The plating film is preferably thicker than the depth of the grooves.

Copper, gold, or silver, which have high thermal conductivity, can also be formed on the mounting surface as a sprayed film. The film in such instances preferably has a thickness of 100 μm or more, as with the above-described plating. Spraying allows the mounting surface to be processed inexpensively, as with plating, and is therefore preferable. It shall be apparent that plating and spraying can also be combined.

A heater, cooling module, or other temperature-controlling mechanism can be provided to the lower part of the holding member. For example, a cooling module 5 can be provided to the lower part of the holding member 3, as shown in FIG. 3. The cooling module disperses heat when the wafer, mounting stage, or holding plate must be cooled, thereby rapidly cooling the holding member or mounting stage.

The cooling module can be moveable. With a moveable cooling module, the temperature can efficiently be increased for the purpose of heating the wafer, mounting stage, and holding member by separating the cooling module from the holding member; and, for cooling purposes, the cooling module is brought into contact with the holding member to achieve rapid cooling. The method for making the cooling module move employs an air cylinder or another raising/lowering means. Using a moveable cooling module is preferred since the cooling rate of the wafer, mounting, and holding member will dramatically improve and throughput will increase. Such a method is also preferable in that the cooling module will not deform under pressure from the cooling module because the probe card does not exert any pressure on the cooling module during probing; and the cooling performance is greater than that of air cooling, in which cool air is blown on the holding member.

If the rate at which the wafer, mounting stage, and holding member are cooled is of greater importance, the cooling module may be fixed to the holding member. In an embodiment in which the cooling module is fixed, the cooling module 5 can be fixed to the lower surface of the holding member 3, as shown in FIG. 3. A deformable and heat-resistant flexible material having high thermal conductivity can also be inserted between the holding member and cooling module. By providing a flexible material that allows the degree of flatness and warping to be alleviated between the holding member and cooling module with respect to each other, the contacting area can be widened further, and the cooling performance of a cooling module as an essential component can be further demonstrated. The cooling rate can therefore be increased. Examples of materials that can be used as the flexible material include silicon, epoxy, phenol, polyimide, and other heat-resistant materials; materials obtained by dispersing BN, silica, AlN, or another filler in the abovementioned resins in order to improve thermal conductivity; and foamed metals.

There are no particular limitations regarding the method for fixing the cooling module. For example, the cooling module can fixed using a mechanical technique such as screwing or clamping. When the holding member and cooling module are fixed via screwing, the use of three or more screws or even six or more screws will increase adhesion between the members and further improve the cooling capacity, and is therefore preferable. In the present structure, the holding member and cooling module are fixed; therefore, a higher cooling rate can be achieved in comparison to when the members are moveable.

The holding member and cooling module can also be integrated. There are no particular limitations regarding the materials used for the holding member and cooling module when the members are integrally formed. However, a flow channel through which a coolant is circulated must be formed in the cooling module, for which reason the difference between the thermal expansion coefficients of the holding member and cooling module is preferably small, and, as shall be apparent, the components are preferably composed of the same material.

When the holding member and cooling module are integrated, the abovementioned ceramic materials and ceramic/metallic complexes can be used as the materials for the holding member. A flow channel for cooling is formed on a surface of the holding member opposite the surface that is in contact with the mounting stage. A wafer holder can be fabricated by integrating a substrate composed of the same material as the holding member via brazing, glass bonding, or another technique. As shall be apparent, the flow channel may be formed on the substrate of the attaching side, or on both substrates. The holding member and cooling module can also be integrated by being screwed together. In such instances, a configuration must be devised in which the coolant or the like is prevented from flowing out from the resulting flow channel by using an 0-ring or the like.

Integrating the holding member and cooling module thus allows the wafer, mounting stage, and holding member to be cooled more quickly than when the holding member and cooling module are fixed in the above-described manner.

With the present technique, a metallic material can also be used as the material of the integrated holding member. Metallic materials are more readily processed and inexpensive in comparison to the above-described ceramic materials or ceramic and metallic complexes, and therefore allow a flow channel for coolant to be more readily formed. However, when a metallic material is used for the integrated holding member, bending may occur due to pressure applied during probing. For this reason tungsten, molybdenum, and alloys or complexes thereof are preferably used for the material when an integrated configuration is used.

Another conducting layer can be formed on the surface of the wafer-mounting surface in instances where the mounting stage is composed of a metal, where the surface readily oxidizes or deteriorates, or where electrical conductivity is low. The layer can be formed by plating nickel or another oxidation-resistant material, or by combining plating and spraying in the above-described manner.

There are no particular limitations regarding the material of the cooling module. Aluminum, copper, and alloys thereof are preferred for their relatively high thermal conductivity, which allows the heat of the mounting stage and holding member to be dispersed rapidly. A stainless steel, magnesium alloy, nickel, or another metal material can also be used. In addition, an oxidation-resistant metal film made from nickel, gold, or silver can be plated, sprayed, or otherwise formed on the cooling module in order to impart the cooling module with oxidation-resistance.

A ceramic material can also be used for the cooling module. There are no particular limitations regarding such a material. However, aluminum nitride and silicon carbide are preferable because of their relatively high thermal conductivity, which allows heat to be dispersed quickly from the mounting stage and holding member. Silicon nitride and aluminum oxynitride have high mechanical strength and exceptional durability, and are therefore preferable. Alumina, cordierite, steatite, and other oxide ceramic materials are relatively inexpensive and therefore preferable. A variety of materials can thus be selected for the cooling module. Therefore, a material may be selected according to the application. Nickel-plated aluminum and nickel-plated copper are preferred among these materials for their exceptional resistance to oxidation, high thermal conductivity, and relatively low cost.

A coolant may also be circulated through the cooling module. Heat transmitted from the wafer holder to the cooling module is thereby rapidly removed from the cooling module, which improves the rate at which the wafer holder is cooled, and is therefore preferable. Coolant must be circulated when the chuck top is used at a temperature lower than normal temperature. There are no particular limitations regarding the coolant circulated within the cooling module. Examples of coolants that can be selected include water and Fluorinert™. However, water is ideal when taking into account the magnitude of specific heat and cost.

In a preferred example, two copper (oxygen-free copper) plates are prepared and a flow channel for circulating water is machined or otherwise formed in one of the copper plates. The other copper plate is simultaneously joined via brazing to a stainless steel pipe that acts as an inlet and outlet for the coolant. The entire surface of the joined cooling plate is plated with nickel in order to improve resistance to corrosion and oxidation. Additionally, as a separate aspect, a cooling module can be obtained by mounting a coolant-conveying pipe to a cooling plate composed of aluminum, copper, or another metal. A groove having a shape similar to the cross section of the pipe may be formed on the cooling plate, and the cooling efficiency can be further increased by affixing the pipe thereto. A resin, ceramic material, or other thermally conductive material may also be inserted as an intermediate layer in order to improve adhesion between the cooling pipe and the cooling plate.

A heat generator or other temperature-controlling mechanism can be provided in the present invention. There is no particular limitation regarding the position at which the mechanism is mounted. However, when the mechanism must have both a cooling function and a heating function, the holding member is preferably disposed below the mounting stage, and the cooling module and heater are preferably mounted in the stated order below the holding member. The order in which the cooling module and heater are mounted can also be switched.

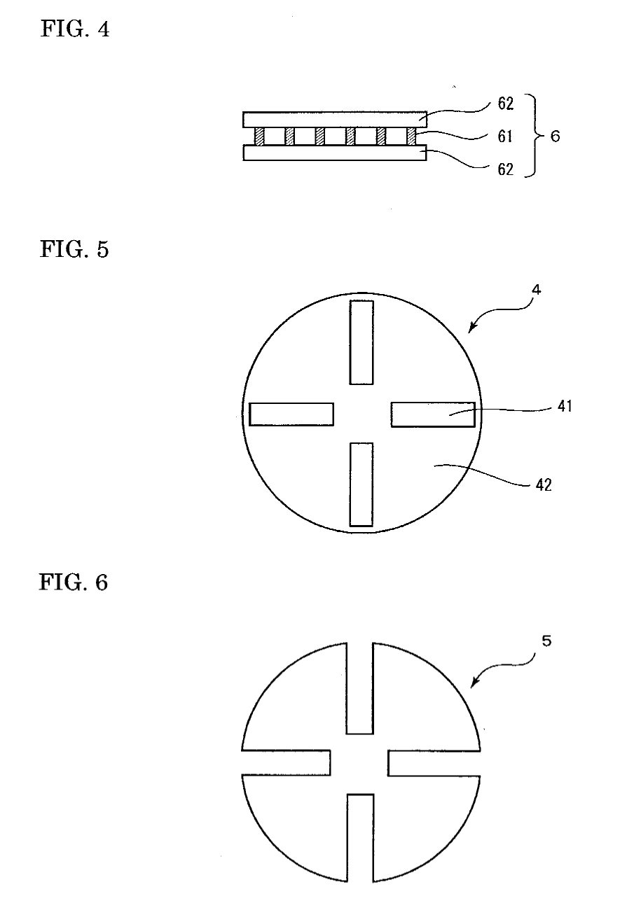

The heat generator can be configured using a variety of structures. For example, the heat generator 6 can be composed of a resistance heat generator 61 sandwiched by, e.g., mica or another insulator 62, as shown in FIG. 4, which is a simple structure and is therefore preferred. A metallic material can be used for the resistance heat generator. For example, a foil or the like made from nickel, stainless steel, silver, tungsten, molybdenum, chromium, or an alloy of these metals can be used as the resistance heat generator. Of these metals, stainless steel and Nichrome™ are preferable. Stainless steel or Nichrome™ can be used to form the circuit pattern of the resistance heat generator with relatively good precision by etching or other methods during the process of shaping the heat generator. These materials are also resistant to oxidation and inexpensive, and are therefore preferable in terms of withstanding usage for long periods of time even at high operating temperatures.

As long as the insulator that sandwiches the heat generator is heat-resistant, the composition thereof is not particularly limited. For example, silicon resins, epoxy resins, phenol resins, and the like may be used in addition to mica, as mentioned above. When the heat generator is sandwiched by such an insulating resin, a filler can be dispersed in the resin so that heat generated by the heat generator will be more evenly conveyed to the mounting stage and holding member. The filler dispersed in the resin acts to increase the thermal conductivity of the silicon resin or other material. The composition of the filler is not particularly limited as long as the material does not react with the resin. Examples include boron nitride, aluminum nitride, alumina, and silica. The heat generator is screwed or otherwise mechanically fixed to a mounting part.

The resistance heat generator may be formed on the holding member or the cooling module by screen printing or another method. In such instances, when the holding member and cooling module are not insulators, the heat generator may be formed after an insulating layer made of glass or another material has been formed on the surface on which the heat generator is to be formed. There are no particular limitations regarding the material of the heat generator. Examples of materials that can be used include silver, platinum, palladium, and alloys and mixtures thereof.

A supporting member is preferably provided in the present invention in order to prevent heat generated by the heat generator from being transmitted to the lower part of the wafer holder. There are no particular limitations regarding the shape of the supporting member, but the supporting member is preferably not in direct contact with the heat generator. For this reason, a shape that allows the supporting member to directly support the holding member is preferred. For example, columnar members 41, which are a plurality of support columns formed into a radial pattern, are provided and a flat part 42 is attached to a lower part to form a supporting member 4, as shown in FIG. 5. In such instances, the cooling module 5 preferably has a shape such as that shown in FIG. 6. There are no limitations regarding the shape or number of the columnar members. However, when the cooling module and heat generator are provided to the lower part of the supporting member, if there is a large number of columnar members or if the columnar members are large in size, the heat generator and cooling module may be interrupted, for which reason caution must be applied because difficulties may arise in the fabrication process.

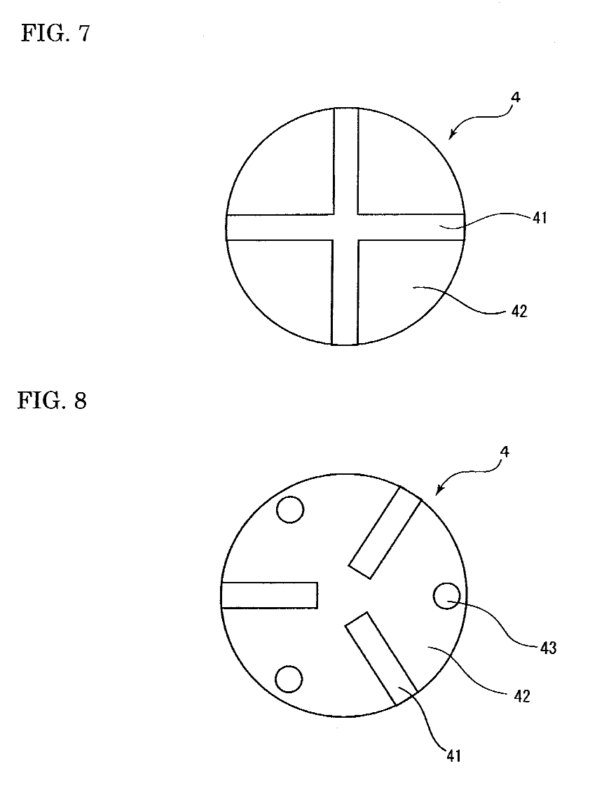

In addition, the column members can be formed into an integrated configuration, as shown in FIG. 7, in order to minimize bending in the holding member and mounting stage. In such instances, the cooling module and heat generator are divided into a plurality of components. In another embodiment, another separate support column 43 is provided between the columnar members 41, as shown in FIG. 8, whereby bending can be reduced.

The thermal conductivity of the supporting member and support columns is preferably lower than the thermal conductivity of the holding member. The temperature of the holding member and mounting stage will therefore also increase when the wafer is heated. However, if heat reaches the lower part of the supporting member, the heat will also be transmitted to the drive system components that are present in the lower part of the holding member and associated with the alignment and other aspects of the wafer. It is undesirable for heat to be transmitted to the components of the drive system because the components will undergo thermal expansion, and the precision of the alignment of the wafer and other components will be impaired. Specific examples of metallic materials that can be used for the supporting member and support columns include stainless steel, iron, and castings thereof.

These materials are preferable because of their relative low cost and low thermal conductivity. A heat-resistant plating or sprayed film composed of nickel, gold, or the like can also be formed on the front surface of the components in order to improve the heat resistance thereof. Examples of ceramic materials that can be used include mullite, alumina, and complexes thereof, which have relatively low thermal conductivity. The columnar members 41, support columns 43, and flat part of the supporting member 4 may be formed separately or integrally. When the members are integrally formed, the cost of assembling the wafer holder can be reduced. When the members are formed separately, the cost of assembly increases, but interfaces are formed between the flat part of the holding member and the columnar members and between the support columns and the flat part of the supporting member. The transmission of heat will accordingly be hindered, and the heat-insulating effect can be enhanced. For this reason, a structure can be selected in accordance with the desired characteristics without particular limitation.

In addition, mounting such a wafer holder to a wafer holder for use in wafer inspection will result in a device that has exceptional heating uniformity and thermal insulation and that is inexpensive, which is preferable.

### FIRST EXAMPLE

A mounting stage and holding member were each fabricated using the materials shown below. Specifically, a copper plate having a thickness of 5 mm and a diameter of 320 mm was prepared. Grooves as shown in FIG. 1 were formed thereon, and holes were then machined. The surfaces were then plated with nickel, and the wafer-mounting surface was ground to a mirror finish with a flatness of 5 μm and a surface roughness Ra of 0.02 μm, resulting in a mounting stage.

An Si—SiC complex having a thickness of 10 mm and a diameter of 320 mm was prepared as a holding member. The top and bottom surfaces of the complex were each ground and machined to a flatness and parallelism of 10 μm or less, resulting in a holding member. Next, the columnar members 41 and support columns 43 shown in FIG. 8 were fabricated using a stainless steel casting. The top and bottom surfaces of the support columns were then ground to a flatness and parallelism of 10 μm or less. An alumina substrate having a diameter of 320 mm and a thickness of 10 mm was prepared as the flat part for the supporting member. The top and bottom surfaces of the alumina substrate were also ground to a flatness and parallelism of 10 μm or less.

A cooling module was provided to the lower part of the holding member. The cooling module was formed by mechanically processing a flow channel for circulating coolant onto each of two copper plates that were 5 mm thick and 300 mm in diameter. The cooling module was joined to the holding member via brazing and ports allowing the outward and inward passage of coolant from the side surface of the cooling module were formed. The surfaces were then plated with nickel in order to ensure heat resistance.

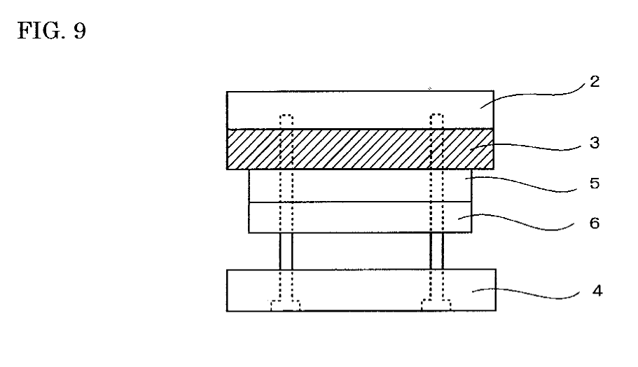

A heat generator was then provided to the lower part of the cooling module. A circuit was formed on the heat generator by etching a 50 μm-thick stainless steel foil, and the heat generator was then sandwiched by a silicon resin into which BN had been dispersed. The mounting stage 2, holding member 3, cooling module 5, and heat generator 6 were integratedly screwed together, as shown in FIG. 9. The integrated members where then mounted to the supporting member 4 and screwed together to form a wafer holder A. The columnar members 41 and support columns 43 are not shown in FIG. 9.

A similar wafer holder B was fabricated for comparison using a copper plate having a diameter of 320 mm and a thickness of 15 mm. A groove and hole for suctioning a wafer were machined without a holding member being provided to the lower part of the copper plate, but a vacuum-suctioning process was not performed on the holding member.

A similar wafer holder C was fabricated for comparison using an Si—SiC substrate having a diameter of 320 mm and a thickness of 15 mm. A groove and hole for suctioning a wafer were machined without a holding member being provided to the lower part of the Si—SiC substrate, but a vacuum-suctioning process was not performed on the holding plate. However, the time required to machine the mounting stage was more than two times that required when copper was used. The cutting tool and the substrate itself broke when machining was performed under the same conditions used with copper.

The characteristics of the copper and Si—SiC in normal temperature are shown in Table 1.

TABLE 1

| | Copper | Si—SiC complex |
|---|---|---|
| Thermal conductivity (W/mK) | 403 | 170 |
| Young's modulus (GPa) | 120 | 280 |

Probing was performed at 180° C. using these materials, and the heating uniformity of the wafer was measured using a wafer-temperature gauge. The heating uniformity was defined as the difference between the maximum and minimum values of the wafer temperature gauge at a heating temperature of 180° C. The results are shown in Table 2.

TABLE 2

| | Wafer holder A | Wafer holder B | Wafer holder C |
|---|---|---|---|
| Structure | Copper: 5 mm | Copper: 15 mm | Si—SiC: 15 mm |
| | Si—SiC: 10 mm | | |
| Machining | Low | Low | High |
| cost | | | |
| Heating | ∘: ±0.7° C. | □: ±0.5° C. | □: ±1.1° C. |
| uniformity | | | |
| (at 180° C.) | | | |
| Results | Good | Deformation in the | Good |
| of probing | | holding part | |
| (deforma- | | | |
| tion in the | | | |
| mounting | | | |
| surface) | | | |

It can be understood from the above results that the wafer holder A of the present invention is exceptional in terms of heating uniformity, cost, and probing.

### INDUSTRIAL APPLICABILITY

According to the present invention, there is provided a prober that has an exceptional heat-insulating structure and that enables weight to be reduced. In addition, a cooling module is provided whereby the rate at which the temperature of the wafer holder is lowered can be improved. Furthermore, the cost of manufacturing a wafer holder can be reduced and heating uniformity can be improved.

1. A wafer holder comprising:
a mounting stage having a mounting surface configured and arranged to mount a wafer; and
a holding member configured and arranged to hold the mounting stage,
the mounting stage having the thermal conductivity K1 and the Young's module Y1 and the holding member having the thermal conductivity K2 and the Young's module Y2 with K1>K2 and Y1<Y2.

2. The wafer holder of claim 1, further comprising
a supporting member disposed in a lower part of the holding member, the supporting member having the thermal conductivity K3 with K2>K3.

3. The wafer holder of claim 1, further comprising
a cooling module disposed on a side of a lower surface of the holding member.

4. The wafer holder of claim 1, further comprising
a heat generator disposed on a side of a lower surface of the holding member.

5. The wafer holder of Claim 1, further comprising
a cooling module disposed on a side of a lower surface of the holding member, and
a heat generator disposed below the cooling module.

6. The wafer holder of claim 2, wherein
the supporting member includes a plurality of columnar members configured and arranged to support the holding member.

7. The wafer holder of claim 1, wherein
the mounting stage has a suction hole for suctioning an object to be mounted.

8. The wafer holder of claim 1, wherein
the mounting stage has a suction hole for suctioning the holding member.

9. A heater unit for a wafer prober comprising the wafer holder of claim 1.

10. A wafer prober comprising the heater unit of claim 9.
